(19) United States
(12) Patent Application Publication
(10) Pub. No.: US 2010/0233853 A1
(43) Pub. Date: Sep. 16, 2010

(54) METHOD FOR MANUFACTURING SEMICONDUCTOR DEVICE

(75) Inventor: Shinji WAKISAKA, Hanno-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/720,760

(22) Filed: Mar. 10, 2010

(30) Foreign Application Priority Data
Mar. 12, 2009 (JP) 2009-059185

(51) Int. Cl. H01L 21/78; H01L 21/60

(52) U.S. Cl. 438/111; 438/119; 438/121; 257/E21.599; 257/E21.509

(57) ABSTRACT

Disclosed is a semiconductor device manufacturing method including: preparing a semiconductor wafer which includes a semiconductor device forming region surrounded by dicing streets extending along first and second directions and including columnar electrodes and a sealing film; with respect to the columnar electrodes nearest the dicing streets in the first direction or the columnar electrodes nearest the dicing streets in the second direction, solder paste layers are displaced to an inward side of the semiconductor device forming region; by performing reflow, allowing the solder paste layer contacting with the columnar electrodes nearest the pair of dicing streets extending in the first direction or the solder paste layer contacting with the columnar electrodes nearest the pair of dicing streets extending in the second direction to move so as to form solder bumps.

### CROSS-REFERENCE TO RELATED APPLICATIONS

This application is based upon and claims the benefit of priority under 35 USC 119 of Japanese Patent Application No. 2009-059185 filed on Mar. 12, 2009, the entire disclosure of which, including the description, claims, drawings, and abstract, is incorporated herein by reference in its entirety.

### BACKGROUND OF THE INVENTION

1. Field of the Invention

The present invention relates to a method for manufacturing a semiconductor device.

2. Description of Related Art

As a conventional semiconductor device, there has been known a device called a chip size package (CSP) (for example, see Japanese Patent Application Laid-Open Publication No. 2005-183868). This semiconductor device is equipped with a semiconductor substrate having a squire shape as viewed from above. In a peripheral part of an upper surface of the semiconductor device, a plurality of joint pads are provided. In a part other than central parts of the joint pads on the upper surface of the semiconductor, an insulating film is provided. On an upper surface of the insulating film, wirings are provided so as to be connected to the joint pads. At predetermined portions of upper surfaces of wirings except upper portions of the joint pads, columnar electrodes are provided. On the insulating film among the columnar electrodes, a sealing film whose upper surface lies in approximately the same plane as upper surfaces of the columnar electrodes is provided. On the upper surfaces of the columnar electrodes, solder bumps are formed. In this case, the columnar electrodes and the solder bumps provided on the upper surface of the columnar electrodes are placed in a matrix.

In such semiconductor device, as a method for forming the solder bumps on the upper surfaces of the columnar electrodes, there has been known a method including: using a solder paste printing mask provided with opening portions for solder paste printing in portions respectively corresponding to the columnar electrodes; printing the solder pastes on the upper surface of the columnar electrodes; and performing reflow steps to form the solder bumps on the upper surfaces of the columnar electrodes (for example, see Japanese Patent Application Laid-Open Publication No. 2005-183868). In such method for forming the solder bumps, sometimes voids occur in the solder bumps due to solder paste printing so that intensity of the solder bumps lowers.

On the other hand, in a field of a wiring substrate, in the case of soldering a base end portion of a pin onto a pad formed on the wiring substrate to form a Pin Grid Alley (PGA) wiring substrate, there has been known a method for evolving air included in voids inside solder paste to prevent corrosion in a joint portion (for example, see Japanese Patent Application Laid-Open Publication No. 2004-55827). Japanese Patent Application Laid-Open Publication No. 2004-55827 describes that when performing printing while displacing the solder paste so that parts of the PGA pads placed in a matrix are exposed to place the base end portion of the pin on the surface of each of the PGA pads to perform reflow steps, air trapped in the voids inside the solder paste is evolved outside with fluidity of the solder paste (especially, see paragraph 39). However, this can be said only for the case of forming the PGA wiring substrate. Although this document describes a method for forming the solder bump on a Flip Chip (FC) pad, in this case, the solder paste is printed on the whole surface of the FC pad (see paragraph 31). Here, the PGA pads to which the base end portions of the pins are soldered respectively and the printing position of the solder paste will be described in detail with reference to FIG. 18, based on Japanese Patent Application Laid-Open Publication No. 2004-55827. In FIG. 18, PGA pads 32 are placed in a square region on a wiring substrate 31 in a matrix of 5 lines and 5 columns for example.

A solder paste printing mask 33 provided with solder paste printing opening portions 34 each having a circular shape as viewed from above and the same size as that of each of the PGA pads (hereinafter referred to as pads 32) are placed so that the solder paste printing opening portions 34 are displaced to the right side respectively with respect to the pads 32 by a radius of each of the pads 32, and then the solder pastes are printed in approximately right half regions of the whole surfaces of the pads 32 and in regions of the wiring substrate 31 adjacent to the right side of the pads 32 to form solder paste layers 35 each having a circular shape when seen from the above so that reflow steps are performed. Japanese Patent Application Laid-Open Publication No. 2004-55827 described that by this method, the melted solder flows toward regions where the PGA pads 32 are exposed due to a self-alignment effect, and thereby solder layers are formed on only upper surfaces of the pads 32.

Here, a semiconductor wafer has dicing streets around each semiconductor device forming region, and after integrated circuits are formed, by dicing along the dicing streets, each semiconductor device is obtained. In FIG. 18, when regarding the wiring substrate 31 as a semiconductor wafer and regarding regions indicated by reference number 36 as dicing streets, the semiconductor paste layers 35 printed correspondingly to the pads 32 placing in the most right column within each semiconductor device forming region enclosed by the dicing streets 36 are placed so as to be displaced toward the right-side dicing street 36 by the radius of each of the pad 32.

In each semiconductor device forming region, an allowable dimension of a distance between the dicing street 36 and the pads 32 in the column nearest this dicing street 36 is for example about 0.05-0.06 mm, because an ability of alignment accuracy of the device is such value.

Although details will be described later, in order to enlarge an effect of inhibiting occurrence of voids after reflow, each positional displacement amount of solder paste layers 35 printed correspondingly to the pad 32 needs to be larger than the allowable dimension. However, if the positional displacement amount of the solder paste layer 35 printed correspondingly to the pad 32 exceeds the allowable dimension, the solder paste layers 35 printed correspondingly to the pads 32 placed in the most right column within the semiconductor device forming region exceeds the right-side dicing street 36 to contact with the pads 32 placed in the most left column within the right-side semiconductor device forming region, and thereby a short circuit occurs. For this reason, a distance A between the dicing street 36 and the pads 32 in the column nearest this dicing street 36 is allowed to be larger than the allowable dimension so as to prevent an occurrence of a short circuit.

When each pitch of the pads 32 is 0.5 mm, each diameter of the pads 32 is 0.25 mm and the solder paste printing mask 33 is placed so that the solder paste printing opening portions 34 are displaced to the right side with respect to the pads 32 by the radius (0.125 mm) of each of the pads 32 for example, in order to prevent the occurrence of the above-mentioned short circuit, the distance A between the dicing street 36 and the pads 32 in the column nearest this dicing street 36 is allowed to be at least about 0.1 mm in view of the allowable dimension. This dimension is extremely larger than the allowable dimension. Thus, according to the conventional method, there is a problem that the planar size of the semiconductor device forming region becomes relatively larger.

### SUMMARY OF THE INVENTION

One object of the present invention is to provide a manufacturing method capable of allowing a planar size of a semiconductor device to be small.

A method for manufacturing a semiconductor device according to the present invention including: preparing a semiconductor wafer which includes a semiconductor device forming region surrounded by a plurality of dicing streets extending along a first direction and a second direction different from the first direction, and in which semiconductor device forming region a plurality of columnar electrodes are provided and a sealing film is formed around the columnar electrodes; forming solder paste layers corresponding to the columnar electrodes nearest one of a pair of dicing streets extending along the first direction and the columnar electrodes nearest the other of the pair of the dicing streets extending along the first direction in positions displaced to an inward side of the semiconductor device forming region with respect to the corresponding columnar electrodes and on the corresponding columnar electrodes respectively, or solder paste layers corresponding to the columnar electrodes nearest one of a pair of dicing streets extending along the second direction and the columnar electrodes nearest the other of the pair of the dicing streets extending along the second direction in positions displaced to an inward side of the semiconductor device forming region with respect to the corresponding columnar electrodes and on the corresponding columnar electrodes respectively; and by performing reflow, allowing the solder paste layer contacting with the plurality of columnar electrodes nearest the pair of dicing streets extending in the first direction or the solder paste layer contacting with the plurality of columnar electrodes nearest the pair of dicing streets extending in the second direction to move so as to form solder bumps.

Preferably, the method may further include: after forming the solder bumps, cutting the semiconductor wafer along the dicing streets to divide the semiconductor wafer into a plurality of semiconductor devices.

Preferably, the method may further include: preparing a solder paste printing mask in which among the plurality of solder paste printing opening portions respectively corresponding to the columnar electrodes in the semiconductor device forming region, the plurality of solder paste printing opening portions corresponding to the plurality of columnar electrodes nearest any of the pair of dicing streets extending to the first direction or the plurality of columnar electrodes nearest any of the pair of dicing streets extending to the second direction are displaced to the inward direction of the semiconductor device forming region with respect to the columnar electrodes and formed in positions respectively overlapping the columnar electrodes; placing the solder paste printing mask on the semiconductor wafer; and printing solder paste within the solder paste printing opening portions of the solder paste printing mask to form the solder paste layers.

Preferably, the solder paste layers corresponding to the columnar electrodes which are nearest one of the dicing streets extending to the first direction may be displaced to a perpendicular direction with respect to the one of the dicing streets extending to the first direction, and the solder paste layers corresponding to the columnar electrodes which are nearest one of the dicing streets extending to the second direction may be displaced to a perpendicular direction with respect to the one of the dicing streets extending to the second direction.

Preferably, the solder paste layers respectively corresponding to the plurality of columnar electrodes nearest any of the dicing streets along the first direction may be displaced to the inward side of the semiconductor device forming region along the second direction with respect to the corresponding columnar electrodes, and at least parts of the solder paste layers respectively corresponding to the columnar electrodes nearest any of the dicing streets along the second direction except the solder paste layers respectively corresponding to the plurality of columnar electrodes nearest any of the dicing streets along the first direction may be displaced to the inward side of the semiconductor device forming region along the second direction.

Preferably, the solder paste layers respectively corresponding to the plurality of columnar electrodes nearest any of the dicing streets along the first direction may be displaced to the inward side of the semiconductor device forming region along the second direction with respect to the corresponding columnar electrodes, and at least parts of the solder paste layers respectively corresponding to the columnar electrodes nearest any of the dicing streets along the second direction except the solder paste layers respectively corresponding to the plurality of columnar electrodes nearest any of the dicing streets along the first direction may be displaced to the inward side of the semiconductor device forming region along a perpendicular direction with respect to the second direction.

Preferably, the solder paste layers respectively corresponding to the plurality of columnar electrodes nearest any of the dicing streets along the second direction may be displaced to the inward side of the semiconductor device forming region along the first direction with respect to the corresponding columnar electrodes, and the solder paste layers respectively corresponding to the columnar electrodes nearest any of the dicing streets along the first direction except the solder paste layers respectively corresponding to the plurality of columnar electrodes nearest any of the dicing streets along the second direction may be displaced to the inward side of the semiconductor device forming region along the first direction.

Preferably, parts of the solder paste layers respectively corresponding to the plurality of columnar electrodes which are nearest any of the dicing streets along the first direction and nearest any of the dicing streets along the second direction may be displaced to the inward side of the semiconductor device forming region along a third direction different from the first and second directions with respect to the corresponding columnar electrodes, and the other parts of the solder paste layers respectively corresponding to the plurality of columnar electrodes which are nearest any of the dicing streets along the first direction and nearest any of the dicing streets along the second direction may be displaced to the inward side of the semiconductor device forming region along a fourth direction different from the first, second and third directions with respect to the corresponding columnar electrodes.

Preferably, the solder paste layers respectively corresponding to the columnar electrodes nearest corners of the semiconductor device forming region may be displaced to the inward side of the semiconductor device forming region in an oblique direction with respect to the corresponding columnar electrodes.

Preferably, with regard to parts of the columnar electrodes provided more inside than the plurality of columnar electrodes nearest any of the pair of dicing streets extending along the first direction in the semiconductor device forming region, a displacement direction of the solder paste layers which correspond to the parts of the columnar electrodes and are formed to be displaced with respect to the parts of the columnar electrodes may be different from a displacement direction of the solder paste layers which correspond to the plurality of columnar electrodes nearest any of the pair of dicing streets extending along the first direction and are formed to be displaced with respect to the plurality of columnar electrodes.

Preferably, each of the columnar electrodes may have a circular shape as viewed from above, the plurality of columnar electrodes in the semiconductor device forming region may be arranged in a matrix, and each of the columnar electrodes may have a rectangle shape as viewed from above.

According to the present invention, the planar size of the semiconductor device can be small.

### BRIEF DESCRIPTION OF THE DRAWINGS

The present invention will sufficiently be understood by the following detailed description and accompanying drawing, but they are provided for illustration only, and not for limiting the scope of the invention.

FIG. 1 is a plain view of an example of a semiconductor device manufactured by a manufacturing method according to the present invention;

FIG. 2 is a cross-section view of a portion along line II-II of FIG. 1;

FIG. 3 is a plain view of a part of an initially prepared object when manufacturing the semiconductor device shown in FIG. 1;

FIG. 4 is a cross-section view of a portion along line IV-IV of FIG. 3;

FIG. 5 is a plain view of a step subsequent to FIG. 3;

FIG. 6 is a cross-section view of a portion along line VI-VI of FIG. 5;

FIG. 7 is a plain view of a step subsequent to FIG. 5;

FIG. 8 is a cross-section view of a portion along line VIII-VIII of FIG. 7;

FIG. 9 is a plain view of a step subsequent to FIG. 7;

FIG. 10 is a cross-section view of a portion along line X-X of FIG. 9;

FIG. 11 is a plain view of a step subsequent to FIG. 9;

FIG. 12 is a cross-section view of a portion along line XII-XII of FIG. 11;

FIG. 13 is a plain view of a step subsequent to FIG. 12;

FIG. 14 is a plain view similar to FIG. 9, explaining about other example of printing positions of solder paste layers with respect to column electrodes;

FIG. 15 is a plain view similar to FIG. 9, explaining about additional example of printing positions of solder paste layers with respect to the column electrodes;

FIG. 16 is a plain view of other example of the semiconductor device manufactured by the manufacturing method according to the present invention;

FIG. 17 is a plain view of a state in which the solder paste layers are formed with respect to the column electrodes in the method for manufacturing the semiconductor device shown in FIG. 16; and

FIG. 18 is a plain view for explaining about an example of a method for forming solder bumps of a conventional semiconductor device.

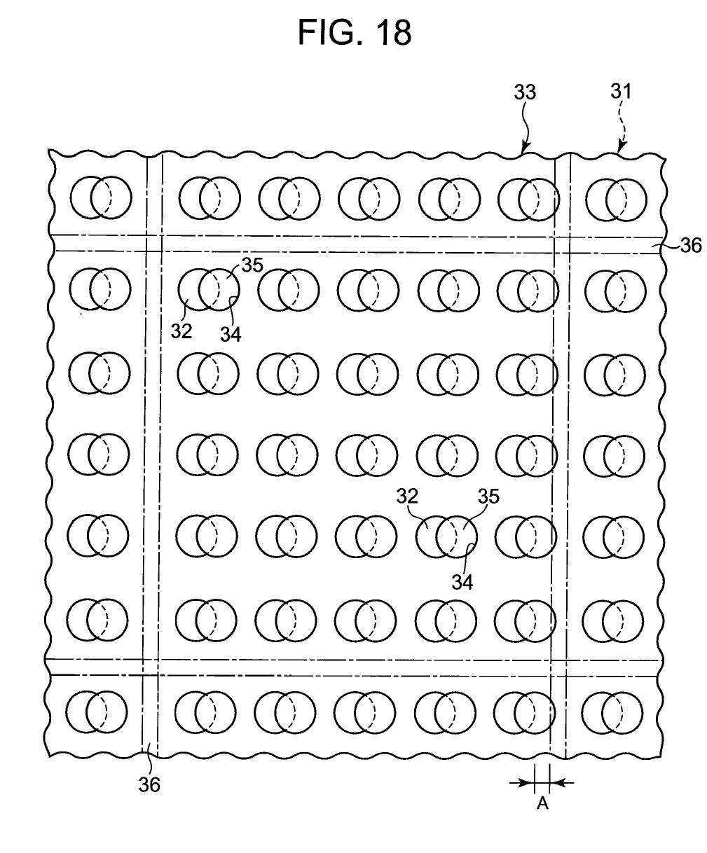

### DETAILED DESCRIPTION OF THE PREFERRED EMBODIMENTS

In the following, the best modes for implementing the present invention will be described with reference to the drawings. Although technically preferable various limitations for implementing the present invention are given to the embodiments described below, the limitations are not intended to limit the scope of the present invention to the following embodiments and shown examples.

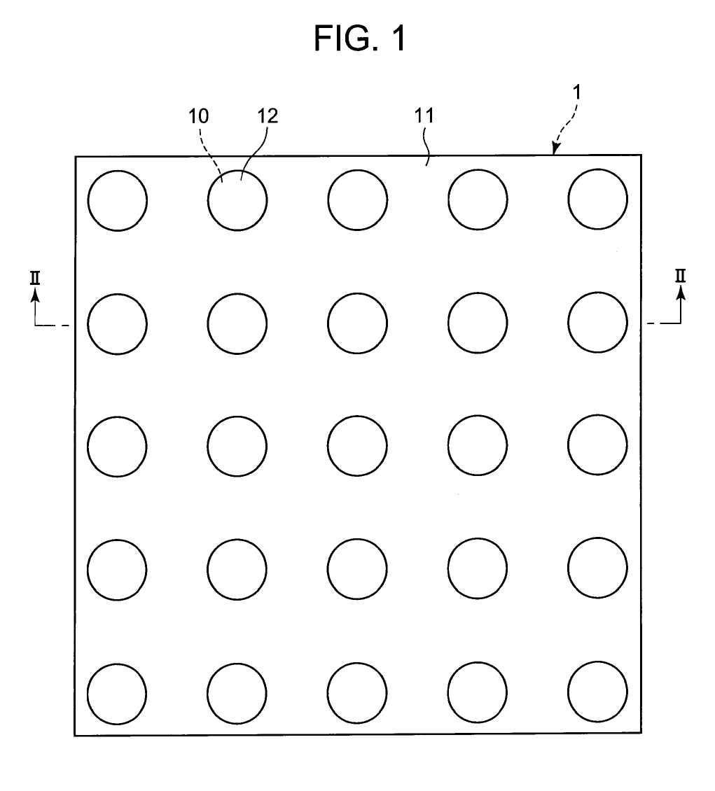

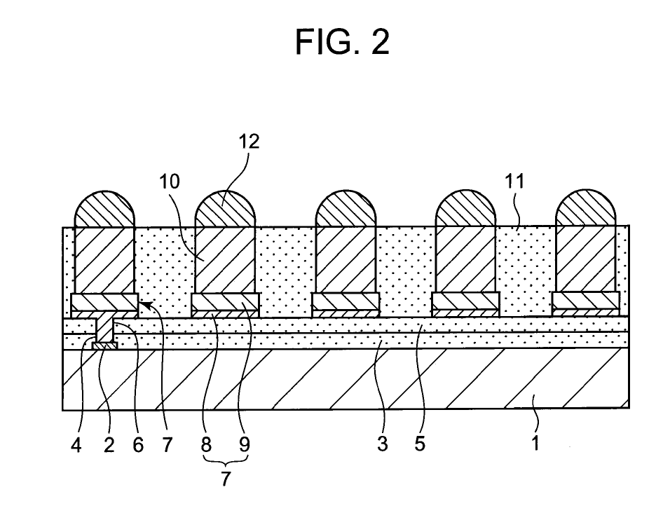

FIG. 1 shows a plain view of an example of a semiconductor device manufactured by a manufacturing method according to the present invention, and FIG. 2 shows a cross-section view of a portion along line II-II of FIG. 1. This semiconductor device is generally called CSP, and equipped with a silicon substrate (semiconductor substrate) 1 having a squire shape as viewed from above. On an upper surface of the silicon substrate 1, elements constructing an integrated circuit having a predetermined function, for example elements (not shown) such as a transistor, diode, resistance and capacitor are formed, and in a peripheral part of the upper surface, joint pads 2 composed of aluminum system metal and the like each being connected to each element of the integrated circuit are provided. Although only two joint pads 32 are shown, in fact, a number of joint pads 32 are arranged in the peripheral part of the upper surface of the silicon substrate 1.

On the upper surface of the silicon substrate 1 except central parts of the joint pads 2, a passivation film 3 composed of oxide silicon and the like is provided, the central parts of the join pads 2 are exposed through opening portions 4 formed in the passivation film 3. On an upper surface of the passivation film 3, a protection film 5 composed of polyimide system resin is provided. In positions of the protection film 5 respectively corresponding to the opening portions 4 of the passivation film 3, opening portions 6 are formed.

On an upper surface of the protection film 5, wirings 7 are provided. Each of the wirings 7 has a dual structure of an underlying metal layer 8 composed of copper and the like and provided on the upper surface of the protection film 5, and an upper metal layer 9 composed of copper and provided on an upper surface of the underlying metal layer 8. One end portions of the wirings 7 are respectively connected to the joint pads 2 through the openings 4, 6 of the passivation film 3 and the protection film 5.

On upper surfaces of joint pad portions of the wirings 7, columnar electrodes 10 composed of copper are provided. On the upper surface of the protection film 5 around the wirings 7 and the columnar electrodes 10, a sealing film 11 composed of epoxy resin and the like is provided. The columnar electrodes 10 are formed so that the upper surfaces of the columnar electrodes 10 lie in the same place as or are several μm lower than an upper surface of the sealing film 11. On the upper surfaces of the columnar electrodes 10, solder bumps 12, each having an approximately semispherical shape, are provided. In this case, as shown FIG. 1, each of the columnar electrodes 10 and the solder bumps 12 formed thereon has a circular shape as vied from above, and they are arranged in a matrix.

(First Embodiment of Manufacturing Method)

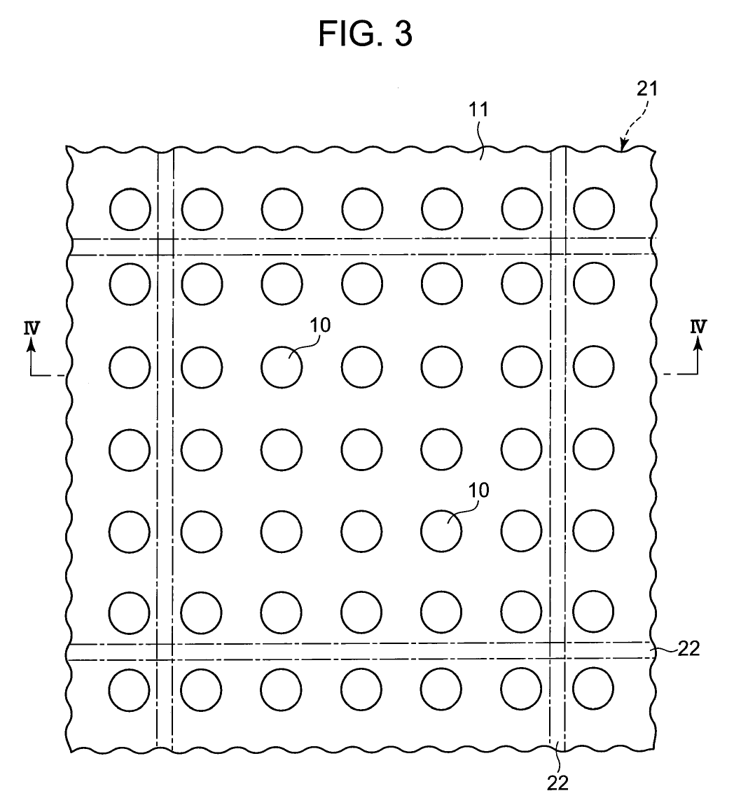

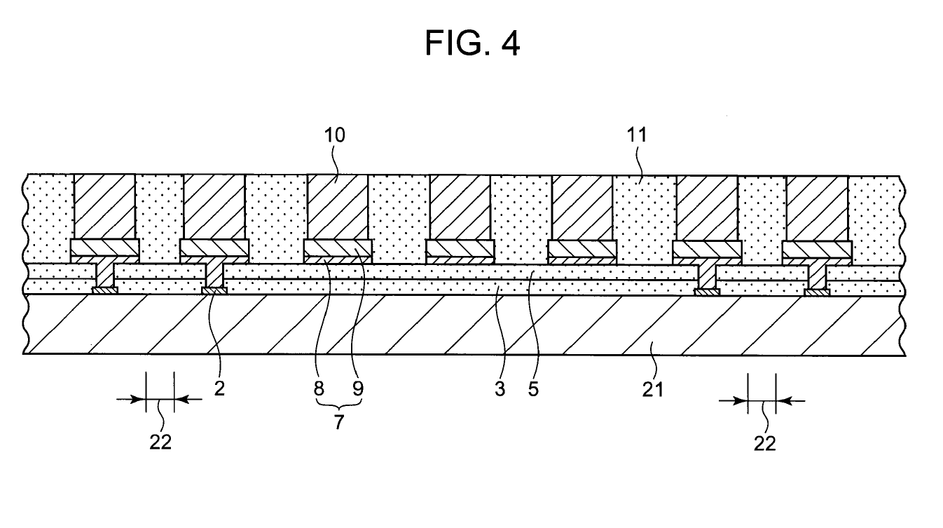

Next, the first embodiment of the method for manufacturing the semiconductor device will be described. Firstly, objects shown in FIGS. 3 and 4 are prepared. In this case, FIG. 3 shows a plain view of a part of the silicon substrate (hereinafter referred to as a semiconductor wafer 21) in a wafer state, namely a region for forming one semiconductor device, and its surroundings, and FIG. 4 shows a cross-section view of a portion along line IV-IV of FIG. 3. In FIGS. 3 and 4, regions indicated by reference number 22 are dicing streets.

In the prepared objects, the joint pads 2, the passivation film 3, the protection film 5, the wiring 7 having the dual structure of the underlying metal layer 8 and the upper metal layer 9, the columnar electrodes 10 and the sealing film 12 are formed on the semiconductor wafer 21. In this case, as shown in FIG. 3 as an example, each of the columnar electrodes 10 has a circular shape as viewed from above. The columnar electrodes 10 are arranged in a matrix of 5 lines×5 columns within the region for forming one semiconductor device surrounded by the dicing streets 22.

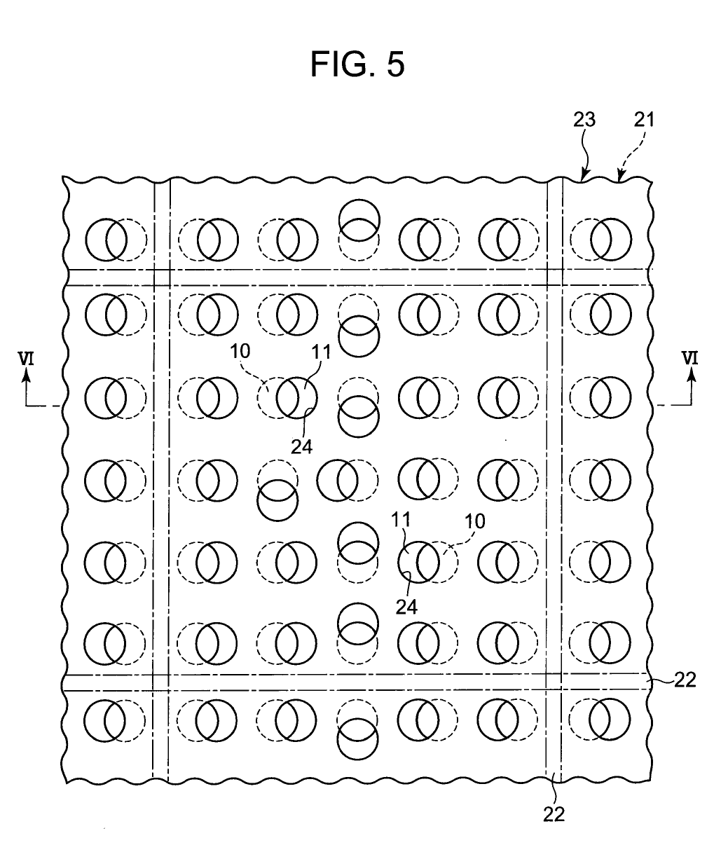

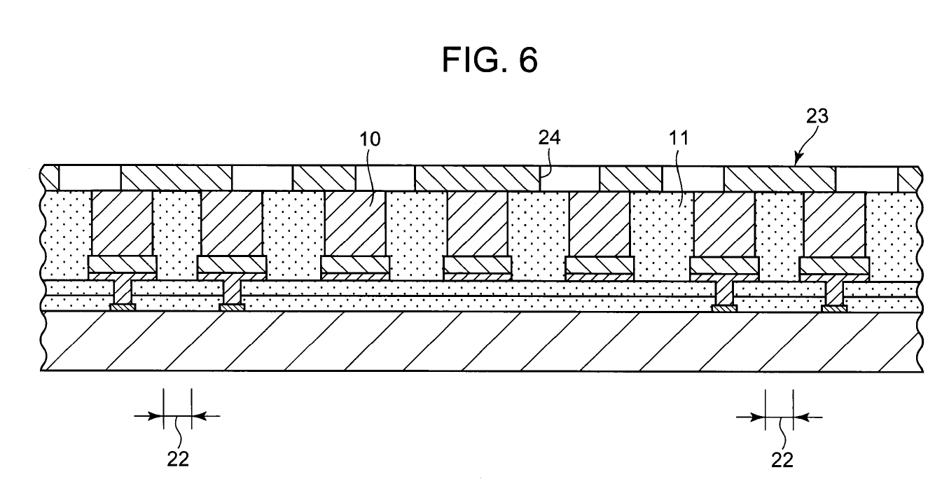

Next, as shown in FIGS. 5 and 6, the solder paste printing mask 23 is prepared. The solder paste printing mask 23 is provided with solder paste printing opening portions 24 each having a planar size depending on the planar size of each of the columnar electrodes 10 and each being placed in a predetermined position displaced from the position corresponding to each columnar electrode 10 to a predetermined direction by the radius of each of the columnar electrodes 10.

In other words, as shown in FIG. 5, within the region corresponding to the semiconductor device forming region surrounded by the dicing streets 22, the solder paste printing opening portions 24 are placed so as to be displaced to the right side with respect to all of the columnar electrodes 10 in the first column by the radius (radius of the solder ball 10). With respect to the columnar electrodes 10 in the first, second, fourth and fifth lines in the second column, the solder paste printing opening portions 24 are placed in positions displaced to the right side by the radius, and with respect to the columnar electrode 10 in the third line in the second column, the solder paste printing opening portion 24 is placed in a position displaced to the lower side by the radius.

With respect to the column electrodes 10 in the first and second lines in the third column, the solder paste printing opening positions 24 are placed in positions displaced to the lower side by the radius, with respect to the columnar electrode 10 in the third line in the third column, the solder paste printing opening position 24 is placed a position displaced to the left side by the radius, and with respect to the columnar electrodes 10 in the fourth and fifth lines in the third column, the solder paste printing opening positions 24 are displaced to the upper side by the radius.

With respect to all columnar electrodes 10 in the fourth column, the solder paste printing opening portions 24 are placed in positions displaced to the left side by the radius, and with respect to all column electrodes 10 in the fifth column, the solder paste printing opening portions 24 are displaced to the left side by the radius.

In other words, in the region corresponding to the semiconductor device forming region surrounded by the dicing streets 22, the solder paste printing opening portions 24 respectively corresponding to the columnar electrodes 10 (a plurality of columnar electrodes 10 next to any of the dicing streets along an vertical direction, being arranged along the vertical direction) nearest any of the dicing streets 22 along the vertical direction (for example, the first direction) in FIG. 5 are displaced in a perpendicular direction with respect to the nearest dicing streets by the radius. Thus, the solder paste printing opening portions 24 corresponding to the columnar electrodes 10 nearest any of the columnar electrodes 10 along the vertical direction are displaced to the inward side (center side) of the semiconductor device forming region in comparison with the corresponding columnar electrodes 10 by the radius.

The solder paste printing opening portions 24 respectively corresponding to the columnar electrodes 10 (a plurality of columnar electrodes 10 next to each of the dicing streets along a right and left direction, being arranged in the right and left direction) nearest any of the dicing streets along the right and left direction (for example, the second direction) in FIG. 5 except the solder paste printing opening portions 24 respectively corresponding to the columnar electrodes 10 nearest any of the dicing streets 22 along the vertical direction includes: the solder paste printing opening portions 24 being arranged along a direction parallel to the dicing streets along the right and left direction, and placed on the inward side (center side) of the semiconductor device forming region with respect to the corresponding columnar electrodes 10; and the solder paste printing opening portions 24 being displaced to the inward side (central side) of the semiconductor device forming region along the perpendicular direction (vertical direction) with respect to the dicing streets 22 along the right and left direction by the radius.

Also the solder paste printing opening portions 24 surrounded by the plurality of columnar electrodes 10 nearest any of a pair of the dicing streets in the right and left direction or any of a pair of the dicing streets in the vertical direction, and corresponding to the columnar electrodes 10 placed on the inward side of the above columnar electrodes 10 in the semiconductor device forming region are displaced with respect to the corresponding columnar electrodes 10 by the radius in a similar way.

Therefore, when determining the position of the solder paste printing mask 23 on the upper surfaces of the columnar electrodes 10 and the sealing film 11 to place it thereon, the solder paste printing opening portions 24 of the solder paste printing mask 23 are arranged in positions displaced to a predetermined direction of the right side, left side, upper side or lower side with respect the corresponding columnar electrodes 10 by the radius. In this case, the solder paste printing opening portions 24 respectively corresponding to the columnar electrodes 10 nearest any of the dicing streets 22 along the right and left direction or the dicing streets 22 along the vertical direction do not protrude outside the dicing streets 22. In this state, a part of the upper surface of each columnar electrode 10 and the adjacent upper surface of the sealing film 11 are exposed through the solder paste printing opening portions 24 of the solder paste printing mask 23.

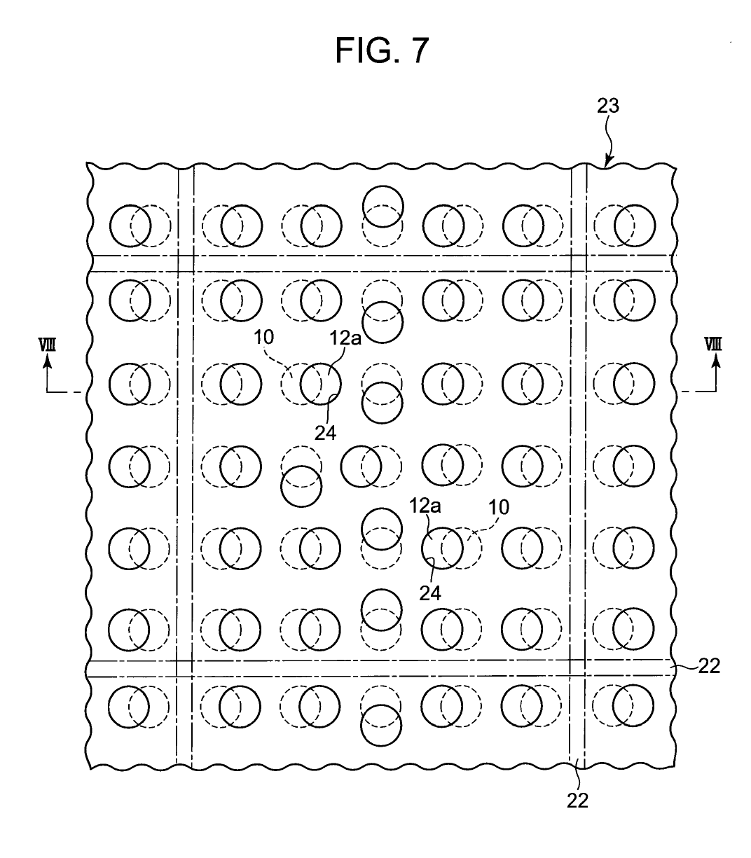

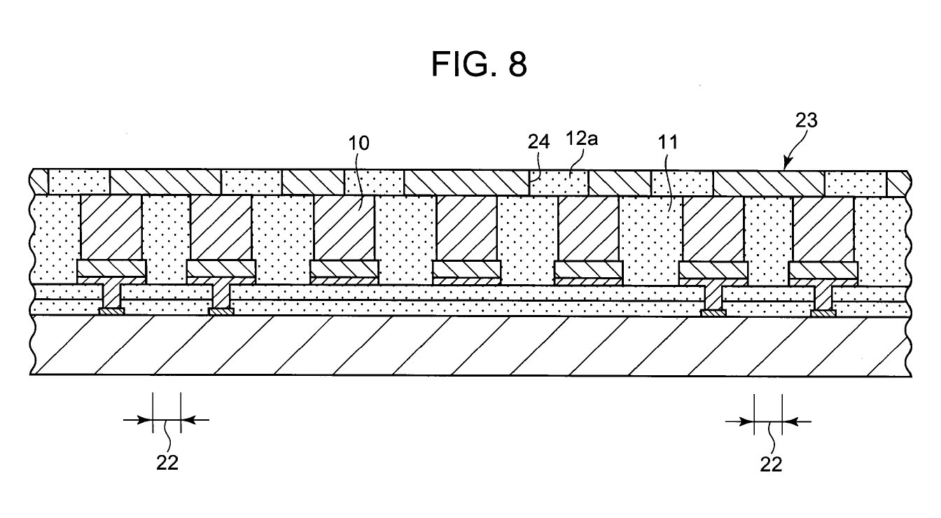

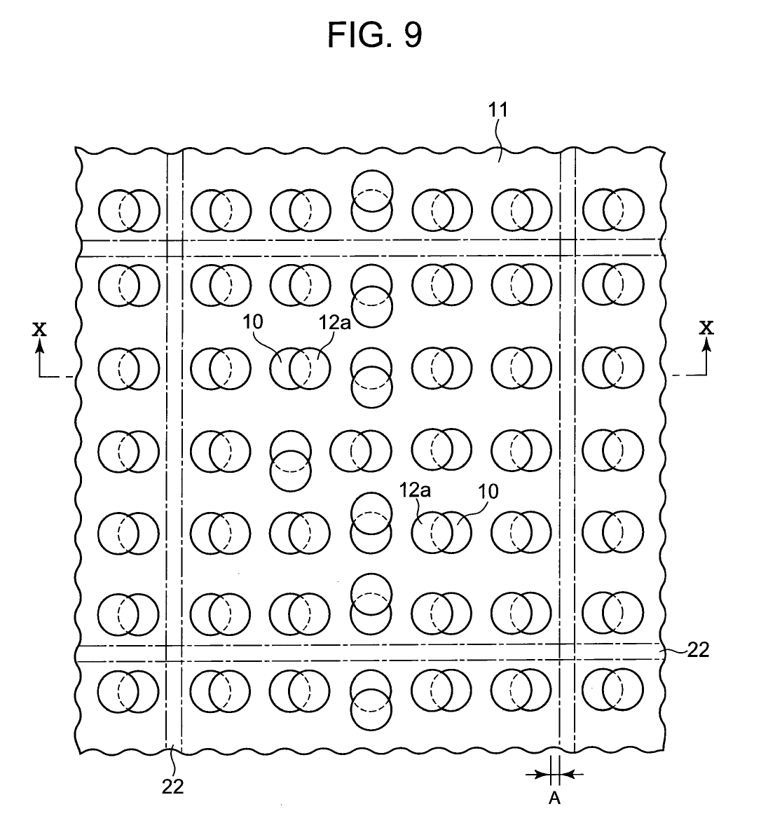

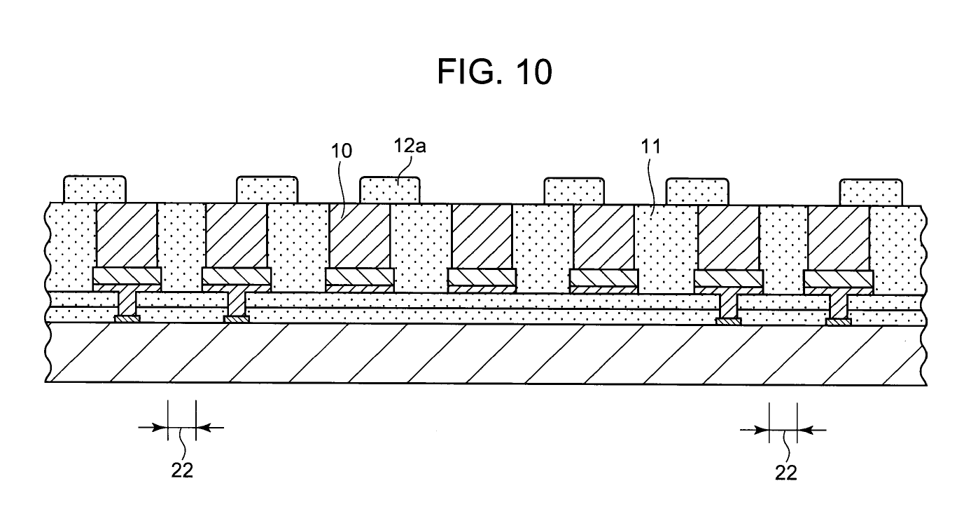

Next, as shown in FIGS. 7 and 8, the solder paste is printed by a screen printing method on the part of the upper surface of each columnar electrode 10 and the adjacent upper surface of the sealing film 11 inside the solder paste printing opening portions 24 of the solder paste printing mask 23 to form solder paste layers 12a. When removing the solder paste printing mask 23, the solder paste layers 12a are arranged on the parts of the upper surfaces of the column electrodes 10 and the adjacent upper surface of the sealing film 11 at positions displaced with respect to the columnar electrodes 10 by the radius as shown in FIGS. 9 and 10.

In this case, since using the solder paste printing mask 23 in which the solder paste printing opening portions 24 corresponding to the plurality of columnar electrodes 10 nearest any of the dicing streets 22 along the vertical direction are displaced to the inward side with respect to the nearest dicing streets 22 by the radius in the direction perpendicular to the vertical direction, within the region corresponding to the semiconductor device forming region surrounded by the dicing streets 22, it becomes possible to prevent the solder paste layers 12a printed correspondingly the columnar electrodes 10 nearest the dicing streets from protruding outside the dicing streets 22.

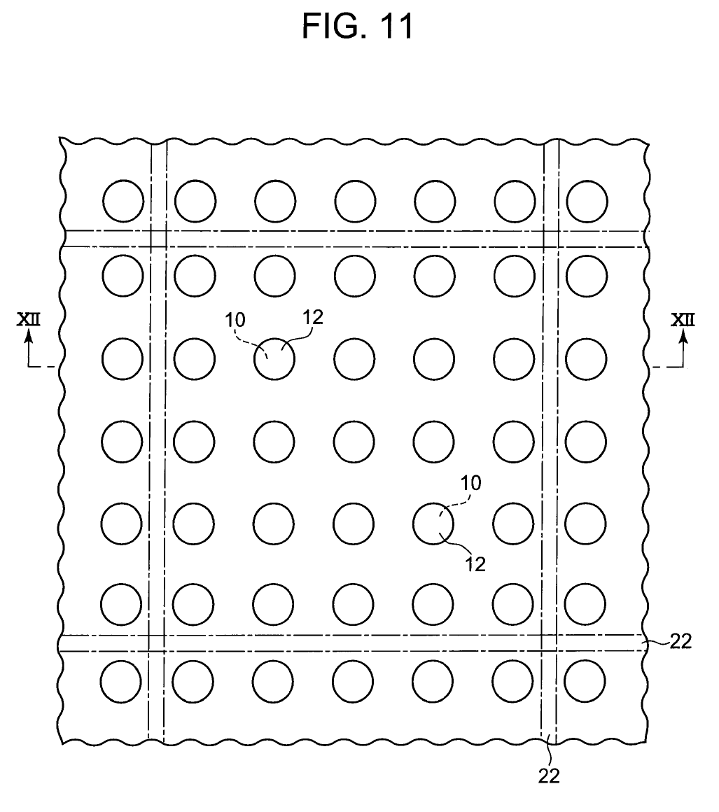

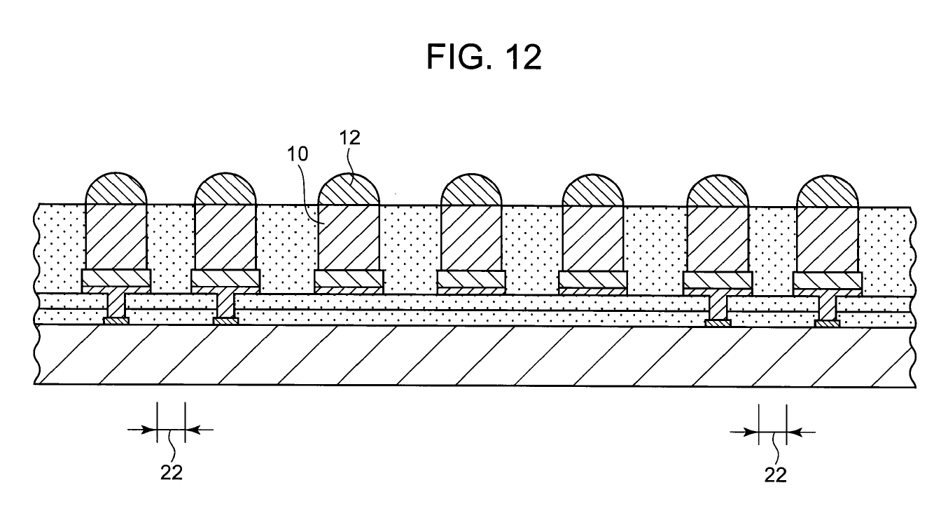

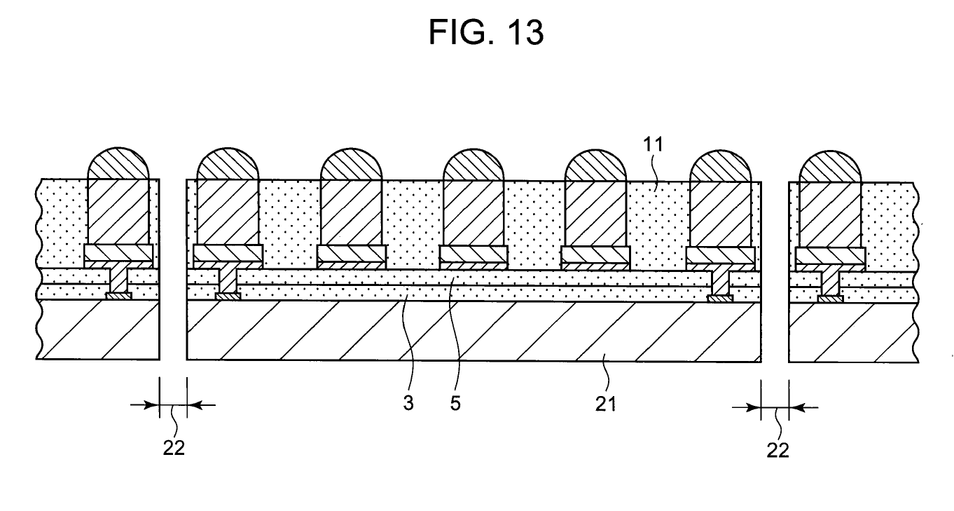

Then, when performing reflow, the solder paste layers 12a melts and the melted solder flows to the whole upper surfaces of the columnar electrodes 10 by surface tension, and thereby the solder bumps 12 having an approximately semispherical shape are formed only on the upper surfaces of the columnar electrodes 10 as shown in FIGS. 11 and 12. In this case, since the melted solder flows to the whole upper surfaces of the columnar electrodes 10, voids are prevented from occurring in the solder bumps 12. Next, as shown in FIG. 13, when cutting the sealing film 11, the protection film 5, the passivation film 3 and the semiconductor wafer 21 along the dicing streets 22, a plurality of semiconductor devices shown in FIGS. 1 and 2 are obtained.

Here, technical contents confirmed by the applicant will be described. When forming the solder paste without displacing from the center of the upper surface of the columnar electrode, after reflow, a number of voids (air holes) due to air contained in the solder paste occur. However, when forming the solder paste at the position displaced from the center of the upper surface of the columnar electrode, the occurrence of voids after reflow is reduced. When each pitch of the columnar electrodes 10 is 0.5 mm and the diameter of each columnar electrode 10 is 0.25 mm, if the displacement amount is 100 μm or more (up to the case of 180 μm were confirmed), a suppression effect of voids becomes largest. If the displacement amount less than such value, the suppression effect of voids decreases, and if the displacement amount is 60 μm or less, the suppression effect of voids further decreases. By this, it is confirmed that the void suppression defect becomes large when the flowing time of the solder paste during reflow becomes long. The void suppression effect is not influenced at all until the difference between the upper surfaces of the columnar electrodes 10 and the upper surface of the sealing film 11 becomes 30 μm, and becomes strong in Pb-less (meaning that “lead is not contained”) solder paste.

As described above, in the method for manufacturing the semiconductor device, by using the solder paste printing mask 23 provided with the plurality of solder paste printing opening portions 24 which correspond to the columnar electrodes within the semiconductor device forming region surrounded by the dicing streets 22, in which mask 23 the solder paste printing opening portions 24 respectively corresponding to the plurality of columnar electrodes 10 nearest any of the dicing streets along the vertical direction are displaced to the inward side (center side) in the semiconductor device forming region, it becomes possible to prevent the semiconductor paste layers 12a printed correspondingly to the columnar electrodes 10 nearest the dicing streets from protruding outside the dicing streets, and thereby the planar size of the semiconductor device can be downsized.

When explaining about the planar size of the semiconductor device with reference to FIG. 9, if each pitch of the columnar electrodes is 0.5 mm, the diameter of each columnar electrode 10 is 0.25 mm, and each displacement amount of the solder paste layers 12a with respect to the columnar electrodes 10 is 0.125 mm for example, since the solder paste layer 12 does not displace to the side of the dicing street 22, if the distance A between each dicing street 22 and the nearest columnar electrodes 10 is 0.05-0.06 mm which is the allowable dimension, the printed solder paste layer 12a does not exceed the dicing streets 22 and does not contact with the adjacent columnar electrodes 10 in the semiconductor device forming region so that a short does not occur. In other words, according to the present invention, the planar size of the semiconductor can be small in comparison with the above-described conventional example.

Incidentally, the printing positions (opening positions of the solder paste printing opening portions 24) of the solder paste layer 12a with respect to the columnar electrodes 10 are not limited to those shown in FIG. 9, and also the following manufacturing method may be adopted.

(Second Embodiment of Manufacturing Method)

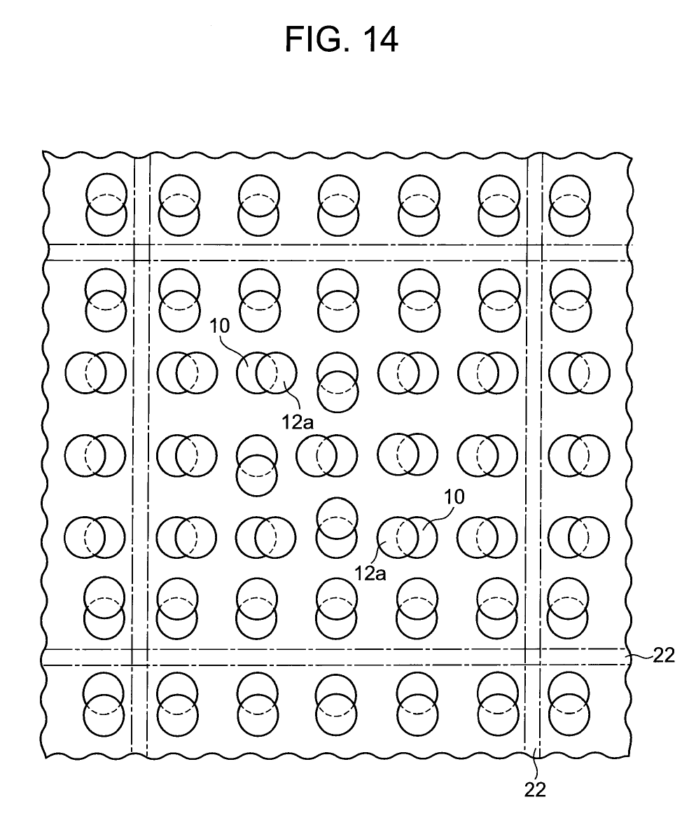

In the second embodiment of the present invention shown in FIG. 14, in the semiconductor device forming region surrounded by the dicing streets 22, with respect to all columnar electrodes 10 in the first line, the solder paste layers 12a are placed so as to be displaced to the lower side by the radius. With respect to the columnar electrodes 10 in the first and second columns in the second line, the solder paste layers 12a are displaced to the right side by the radius. With respect to the columnar electrode 10 in the third column in the second line, the solder paste layer 12a is displaced to the lower side by the radius. With respect to the column electrodes 10 in the fourth and fifth columns in the second line, the solder paste layer 12a is displaced to the left side by the radius.

With respect to the columnar electrode 10 in the first column in the third line, the solder paste layer 12a is displaced to the right side by the radius. With respect to the columnar electrode 10 in the second column in the third line, the solder paste layer 12a is displaced to the lower side by the radius. With respect to the columnar electrodes 10 from the third column to the fifth column in the third line, the solder paste layers 12a are displaced to the right side by the radius.

With respect to the columnar electrodes 10 in the first and second column in the fourth line, the solder paste layers 12a are displaced to the right side by the radius. With respect to the columnar electrode 10 in the third column in the fourth line, the solder paste layer 12a is displaced to the upper side by the radius. With respect to the columnar electrodes 10 in the fourth and fifth column in the fourth line, the solder paste layers 12a are displaced to the left side by the radius. With respect to all columnar electrodes 10 in the fifth line, the solder paste layers 12a are displaced to the upper side by the radius.

In other words, in the region corresponding to the semiconductor device forming region surrounded by the dicing streets 22, the solder paste printing opening portions 24 corresponding to the columnar electrodes 10 (a plurality of column electrodes 10 adjacent to any of the dicing streets 22 along the right and left direction, being arranged along the right and left direction) nearest any of the dicing streets 22 along the right and left direction (for example the second direction) in FIG. 14 are displaced in the perpendicular direction by the radius with respect to the nearest dicing streets 22. In other words, the solder paste printing opening portions 24 respectively corresponding to the columnar electrodes 10 nearest to the dicing street along the right and left direction are displaced to the inward side (center side) of the semiconductor device forming region by the radius in comparison with the corresponding columnar electrodes 10.

The solder paste printing opening portions 24 corresponding to the columnar electrodes 10 (a plurality of columnar electrodes 10 adjacent to any of the dicing streets 22 along the upside and downside direction, being arranged in the vertical direction) nearest any of the dicing streets 22 along the vertical direction (for example the first direction) in FIG. 14 except the solder paste printing opening portions 24 corresponding to the columnar electrodes 10 nearest any of the dicing streets 22 along the right and left direction, are arranged along the direction parallel to the dicing streets 22 in the vertical direction and displaced to the inward side (center side) in the semiconductor device forming region by the radius in comparison with the corresponding column electrodes 10.

Also the solder paste printing opening portions 24 surrounded by the plurality of columnar electrodes 10 nearest any of the pair of the dicing streets 22 in the right and left direction or any of the pair of the dicing streets 22 in the vertical direction, and correspond to the columnar electrodes 10 provided on the inside of the above columnar electrodes 10 in the semiconductor device forming region, are displaced by the radius with respect to the corresponding columnar electrodes 10 in a similar way.

(Third Embodiment of Manufacturing Method)

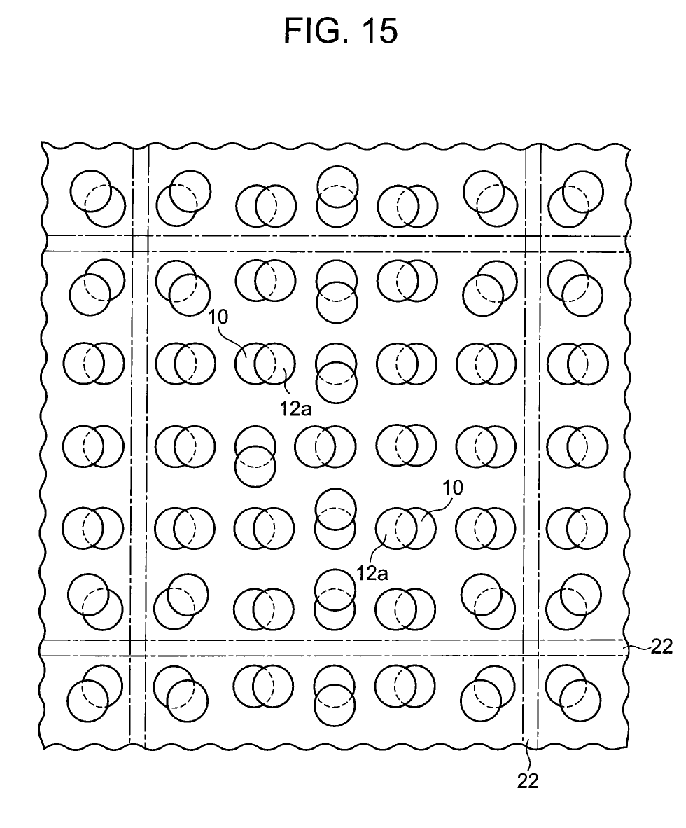

The third embodiment of the present invention shown in FIG. 15 will be described. In the third embodiment shown in FIG. 15, points different from the case of FIG. 9 are: with respect to the columnar electrode 10 in the first column in the first line, the solder paste layer 12a is placed so as to be displaced to a lower right side by the radius; with respect to the columnar electrode 10 in the fifth line in the first column, the solder paste layer 12a is displaced to a upper right side by the radius; with respect to the columnar electrode 10 in the first line in the fifth column, the solder paste layer 12a is displaced to a lower left side by the radius side; and with respect to the column electrode 10 in the fifth line in the fifth column, the solder paste layer 12a is displaced to a upper left side by the radius.

In other words, in the solder paste printing mask, the solder paste printing opening portions placed in corners of the region corresponding to the semiconductor device forming region surrounded by the dicing streets 22 are displaced to the inward side in the semiconductor device forming region in a predetermined oblique direction by the radius with respect to the columnar electrode 10 placed in the corners.

Incidentally, the columnar electrodes 10 are arranged in a matrix in the first-third embodiments, but the matrix of the present invention includes not only a rectangular arrangement where the columnar electrodes 10 are regularly arranged at regular intervals in the right and left direction and vertical direction, but also an arrangement where distances between the columnar electrodes 10 differ somewhat one another, an arrangement where the columnar electrode in every couple of lines (or columns) places between the columnar electrodes in an adjacent line (or column), and an arrangement where there is a region (non-forming region) in which no columnar electrode is formed in a central region of the semiconductor device forming region or in each line (or column).

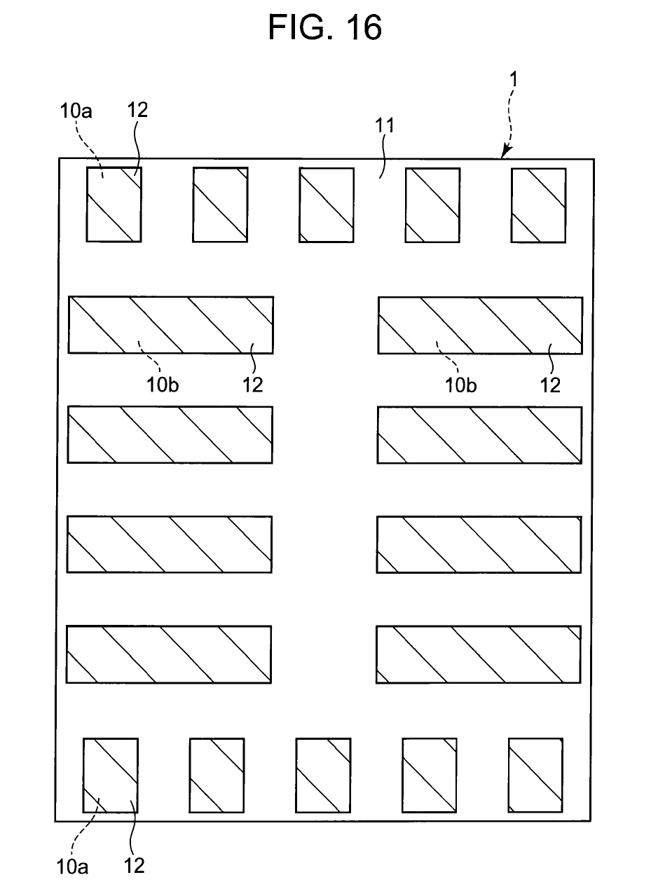

The planar shapes of each electrode 10 and each solder bump 12 as view from above are not limited to circular shapes, and may be a rectangle shape, as another example of the semiconductor device manufactured by the manufacturing method of the present invention shown in FIG. 16. In this case, the five first columnar electrodes 10a each being long from upside to downside (vertically long) are arranged in a line direction at a certain pitch in each of upside and downside on the silicon substrate 1. In each of right and lift side in the central region except the upside and downside on the silicon substrate 1, the four second columnar electrodes 10b being long from right to left (horizontally long) are arranged in a columnar direction at intervals same as the inverbals of the first columnar electrodes 10a.

The line direction length of each first columnar electrode 10a and the columnar direction length of each second columnar electrode 10b are same as an interval between the first columnar electrodes 10a adjacent to each other. An interval between the first columnar electrodes 10a placed on the upside of the silicon substrate 1 and the second columnar electrodes 10b placed on the downside of these first columnar electrodes 10a adjacently thereto is same as the interval between the first columnar electrodes 10a adjacent to each other. An interval between the first columnar electrodes 10a placed on the downside of the silicon substrate 1 and the second columnar electrodes 10b placed on the upside of these first columnar electrodes 10a adjacent thereto is same as the interval between the first columnar electrodes 10a adjacent to each other. An interval between the second columnar electrodes 10b arranged on the right side of the silicon substrate 1 and the second columnar electrodes 10b arranged on the left side to form a pair with those on the right side is twice the interval between the first columnar electrodes 10a adjacent to each other.

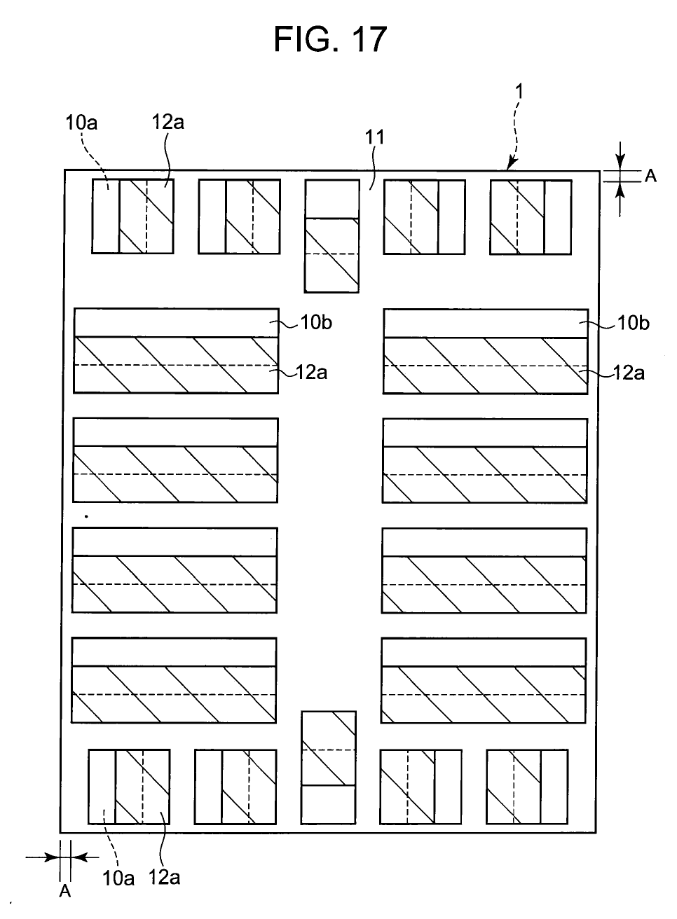

FIG. 17 shows a plain view of a state in which the solder paste layers 12a are formed correspondingly to the first and second column electrodes 10a, 10b in the method for manufacturing the semiconductor device shown in FIG. 16. In this case, with respect to two left-side first columnar electrodes 10a on the upper side of the silicon substrate 1, the solder paste layers 12a are placed in positions displaced to the right side by a half of the distance between the first columnar electrodes 10a adjacent to each other. With respect to two right-side first columnar electrodes 10a on the upper side of the silicon substrate 1, the solder paste layers 12a are placed in positions displaced to the left side by a half of the distance between the first columnar electrodes 10a adjacent to each other. With respect to one central first columnar electrode 10a on the upper side of the silicon substrate 1, the solder paste layer 12a is placed in a position displaced to the downside by a half of the length in the columnar direction of the first columnar electrodes 10a.

With respect to two left-side columnar electrodes 10a on the downside of the silicon substrate 1, the solder paste layers 12a are placed in positions displaced to the right side by a half of the interval between the first columnar electrodes 10a adjacent to each other. With respect to two right-side first columnar electrodes 10a on the downside of the silicon substrate 1, the solder paste layers 12a are placed in positions displaced to the left side by a half of the interval between the first columnar electrodes 10a adjacent to each other. With respect to one central first columnar electrode 10a on the downside of the silicon substrate 1, the solder paste layer 12a is placed in a position displaced to the upside by a half of the length in the columnar direction of the first columnar electrodes 10a. With respect to all second columnar electrodes 10b in the left and right side in the center of the substrate 1, the solder paste layers 12a are placed in positions displaced to the downside by a half of the interval between the first columnar electrodes 10a adjacent to each other.

In other words, the solder paste layers 12a are placed in the positions displaced basically by a half of the interval between the first columnar electrodes 10a adjacent to each other, in a direction along a side surface of the silicon substrate 1 corresponding to one end surface in a width direction of the dicing streets or in a direction perpendicularly departing from the side surface of the silicon substrate 1 and departing from the adjacent solder paste layers 12a, with respect to the corresponding first and second columnar electrodes 10a, 10b. Thus, it becomes possible to prevent the solder paste layers 12a printed correspondingly to all first and second columnar electrodes 10a, 10b from protruding from the side surface of the silicon substrate 1 corresponding to one end surface in the width direction of the dicing streets, and thereby the planar size of the semiconductor device can be small.

As described above, according to the embodiments, by using the solder paste printing mask provided with the plurality of solder paste printing opening portions corresponding to the columnar electrodes within the semiconductor device forming region surrounded by the dicing streets, in which mask the solder paste printing opening portions corresponding to the columnar electrodes nearest any of the pair of dicing streets in the right and left direction or any of the pair of dicing streets in the vertical direction are displaced to the center side of the semiconductor device forming region, it becomes possible to prevent the solder paste layers printed correspondingly to the columnar electrodes nearest the dicing streets from protruding outside the dicing streets.

What is claimed is:

1. A method for manufacturing a semiconductor device, the method comprising:
preparing a semiconductor wafer which includes a semiconductor device forming region surrounded by a plurality of dicing streets extending along a first direction and a second direction different from the first direction, and in which semiconductor device forming region a plurality of columnar electrodes are provided and a sealing film is formed around the columnar electrodes;
forming solder paste layers corresponding to the columnar electrodes nearest one of a pair of dicing streets extending along the first direction and the columnar electrodes nearest the other of the pair of the dicing streets extending along the first direction in positions displaced to an inward side of the semiconductor device forming region with respect to the corresponding columnar electrodes and on the corresponding columnar electrodes respectively, or solder paste layers corresponding to the columnar electrodes nearest one of a pair of dicing streets extending along the second direction and the columnar electrodes nearest the other of the pair of the dicing streets extending along the second direction in positions displaced to an inward side of the semiconductor device forming region with respect to the corresponding columnar electrodes and on the corresponding columnar electrodes respectively; and
by performing reflow, allowing the solder paste layer contacting with the plurality of columnar electrodes nearest the pair of dicing streets extending in the first direction or the solder paste layer contacting with the plurality of columnar electrodes nearest the pair of dicing streets extending in the second direction to move so as to form solder bumps.

2. The method for manufacturing the semiconductor device according to claim 1, the method further comprising:
after forming the solder bumps, cutting the semiconductor wafer along the dicing streets to divide the semiconductor wafer into a plurality of semiconductor devices.

3. The method for manufacturing the semiconductor device according to claim 1, the method further comprising:
preparing a solder paste printing mask in which among the plurality of solder paste printing opening portions respectively corresponding to the columnar electrodes in the semiconductor device forming region, the plurality of solder paste printing opening portions corresponding to the plurality of columnar electrodes nearest any of the pair of dicing streets extending to the first direction or the plurality of columnar electrodes nearest any of the pair of dicing streets extending to the second direction are displaced to the inward direction of the semiconductor device forming region with respect to the columnar electrodes and formed in positions respectively overlapping the columnar electrodes;
placing the solder paste printing mask on the semiconductor wafer; and
printing solder paste within the solder paste printing opening portions of the solder paste printing mask to form the solder paste layers.

4. The method for manufacturing the semiconductor device according to claim 1, wherein
the solder paste layers corresponding to the columnar electrodes which are nearest one of the dicing streets extending to the first direction are displaced to a perpendicular direction with respect to the one of the dicing streets extending to the first direction, and the solder paste layers corresponding to the columnar electrodes which are nearest one of the dicing streets extending to the second direction are displaced to a perpendicular direction with respect to the one of the dicing streets extending to the second direction.

5. The method for manufacturing the semiconductor device according to claim 1, wherein
the solder paste layers respectively corresponding to the plurality of columnar electrodes nearest any of the dicing streets along the first direction are displaced to the inward side of the semiconductor device forming region along the second direction with respect to the corresponding columnar electrodes, and
at least parts of the solder paste layers respectively corresponding to the columnar electrodes nearest any of the dicing streets along the second direction except the solder paste layers respectively corresponding to the plurality of columnar electrodes nearest any of the dicing streets along the first direction are displaced to the inward side of the semiconductor device forming region along the second direction.

6. The method for manufacturing the semiconductor device according to claim 1, wherein
the solder paste layers respectively corresponding to the plurality of columnar electrodes nearest any of the dicing streets along the first direction are displaced to the inward side of the semiconductor device forming region along the second direction with respect to the corresponding columnar electrodes, and
at least parts of the solder paste layers respectively corresponding to the columnar electrodes nearest any of the dicing streets along the second direction except the solder paste layers respectively corresponding to the plurality of columnar electrodes nearest any of the dicing streets along the first direction are displaced to the inward side of the semiconductor device forming region along a perpendicular direction with respect to the second direction.

7. The method for manufacturing the semiconductor device according to claim 1, wherein
the solder paste layers respectively corresponding to the plurality of columnar electrodes nearest any of the dicing streets along the second direction are displaced to the inward side of the semiconductor device forming region along the first direction with respect to the corresponding columnar electrodes, and
the solder paste layers respectively corresponding to the columnar electrodes nearest any of the dicing streets along the first direction except the solder paste layers respectively corresponding to the plurality of columnar electrodes nearest any of the dicing streets along the second direction are displaced to the inward side of the semiconductor device forming region along the first direction.

8. The method for manufacturing the semiconductor device according to claim 1, wherein
parts of the solder paste layers respectively corresponding to the plurality of columnar electrodes which are nearest any of the dicing streets along the first direction and nearest any of the dicing streets along the second direction are displaced to the inward side of the semiconductor device forming region along a third direction different from the first and second directions with respect to the corresponding columnar electrodes, and
the other parts of the solder paste layers respectively corresponding to the plurality of columnar electrodes which are nearest any of the dicing streets along the first direction and nearest any of the dicing streets along the second direction are displaced to the inward side of the semiconductor device forming region along a fourth direction different from the first, second and third directions with respect to the corresponding columnar electrodes.

9. The method for manufacturing the semiconductor device according to claim 1, wherein
the solder paste layers respectively corresponding to the columnar electrodes nearest corners of the semiconductor device forming region are displaced to the inward side of the semiconductor device forming region in an oblique direction with respect to the corresponding columnar electrodes.

10. The method for manufacturing the semiconductor device according to claim 1, wherein
with regard to parts of the columnar electrodes provided more inside than the plurality of columnar electrodes nearest any of the pair of dicing streets extending along the first direction in the semiconductor device forming region, a displacement direction of the solder paste layers which correspond to the parts of the columnar electrodes and are formed to be displaced with respect to the parts of the columnar electrodes is different from a displacement direction of the solder paste layers which correspond to the plurality of columnar electrodes nearest any of the pair of dicing streets extending along the first direction and are formed to be displaced with respect to the plurality of columnar electrodes.

11. The method for manufacturing the semiconductor device according to claim 1, wherein
each of the columnar electrodes has a circular shape as viewed from above.

12. The method for manufacturing the semiconductor device according to claim 1, wherein
the plurality of columnar electrodes in the semiconductor device forming region are arranged in a matrix.

13. The method for manufacturing the semiconductor device according to claim 1, wherein
each of the columnar electrodes has a rectangle shape as viewed from above.
